(19) United States
(12) Patent Application Publication
(10) Pub. No.: US 2024/0407100 A1
(43) Pub. Date: Dec. 5, 2024

(54) ELECTROLYTIC CAPACITORS HAVING ENCLOSURES THAT ENABLE THE CAPACITORS TO BE SURFACE MOUNTED TO A SUBSTRATE

(71) Applicant: Western Digital Technologies, Inc., San Jose, CA (US)

(72) Inventors: Fei Wang, Shanghai (CN); Tan Chong Un, Shanghai (CN); Hui Xu, Shanghai (CN); Weng Khoon Mong, Penang (MY)

(21) Appl. No.: 18/361,061

(22) Filed: Jul. 28, 2023

Related U.S. Application Data
(60) Provisional application No. 63/505,629, filed on Jun. 1, 2023.

(51) Int. Cl. H05K 1/18; H05K 1/11

(52) U.S. Cl. CPC H05K 1/181; H05K 1/111; H01G 9/28; H05K 2201/10015

(57) ABSTRACT

A semiconductor package includes a substrate that defines an opening. The substrate includes multiple solder pads on opposite sides of the opening. An electrolytic capacitor is horizontally positioned within the opening. The electrolytic capacitor includes or is otherwise associated with an enclosure that at least partially surrounds the electrolytic capacitor. The enclosure includes or defines a support bar that extends from a distal end of the enclosure. Leads of the electrolytic capacitor are soldered to a first set of solder pads on one side of the opening while the support bar is soldered to a solder pad on another side of the opening. The support bar maintains a position of the electrolytic capacitor within the opening.

### CROSS-REFERENCE TO RELATED APPLICATIONS

The present application claims priority to U.S. Provisional Application 63/505,629 entitled “ELECTROLYTIC CAPACITORS HAVING ENCLOSURES THAT ENABLE THE CAPACITORS TO BE SURFACE MOUNTED TO A SUBSTRATE”, filed Jun. 1, 2023, the entire disclosure of which is hereby incorporated by reference in its entirety.

### BACKGROUND

Capacitors are typically included with various solid-state drives (SSDs) and/or enterprise solid-state drives (eSSDs). Capacitors store and discharge electrical energy and are used to provide backup power in case of unexpected power outages and/or system failures. Capacitors may also help reduce the likelihood of voltage spikes.

Given the benefits listed above, it may be desirable to include high-capacity capacitors with SSDs and other semiconductor packages. However, some high-capacity capacitors, such as liquid electrolytic capacitors, are typically coupled to a substrate of the SSD using wave soldering or laser soldering, which can be a time-intensive and/or costly process. In other examples, some high-capacity capacitors, such as solid electrolytic capacitors, have a large footprint and/or size. As such, these capacitors do not fit within an enclosure of small form factor SSDs.

Accordingly, it would be beneficial to have high-capacity capacitors that may be easily mounted to a substrate of a SSD or other semiconductor package while still complying with small form factor requirements of the SSD.

### SUMMARY

The present application describes a semiconductor chip or semiconductor package having a horizontally mounted capacitor which enables the semiconductor package to have a small form factor (e.g., a reduced height, a reduced length and/or reduced thickness). In an example, the height or thickness of the semiconductor package may be approximately 6.8 millimeters (mm) or less.

In an example, the capacitor is a vertical-type capacitor. However, using the features described herein, the capacitor may be mounted or otherwise disposed horizontally within the semiconductor package. For example, the capacitor may be an electrolytic capacitor or other capacitor having a high capacity (e.g., 1000 microfarads (μF) or more) and/or voltage (e.g., 35V or more). The electrolytic capacitor may be a liquid electrolytic capacitor or a solid electrolytic capacitor. The electrolytic capacitor may also include or otherwise be associated with a housing or an enclosure that enables the electrolytic capacitor to be horizontally mounted (e.g., using a reflow soldering process) to substrate of the semiconductor package.

For example, the substrate may define or otherwise include an opening that has a shape and/or dimensions to receive the electrolytic capacitor. The substrate may also include multiple solder pads on opposite sides of the opening. Leads of the electrolytic capacitor may be coupled to a first set of solder pads on one side of the opening while a solderable pin or support bar may extend from an enclosure associated with the electrolytic capacitor. The solderable pin or support bar may be coupled to a solder pad on another side of the opening and be used to maintain a position of the electrolytic capacitor within the opening.

In some examples, the electrolytic capacitor is a liquid electrolytic capacitor. In such an example, the enclosure may substantially or entirely surround and/or enclose the electrolytic capacitor and be comprised of a thermal isolation material. As such, the liquid electrolytic capacitor can be soldered to the substrate using a reflow soldering process. In other examples, the electrolytic capacitor is a solid electrolytic capacitor. In such an example, the enclosure may partially surround and/or enclose the electrolytic capacitor. A solderable pin or support bar may extend from the enclosure and be soldered to the substrate using a reflow soldering process.

Accordingly, the present application describes a semiconductor package that includes a substrate that defines an opening. A first solder pad is provided on a surface of the substrate at a proximal side of the opening, a second solder pad is provided on the surface of the substrate proximate to the first solder pad and a third solder pad is provided on the surface of the substrate at a distal side of the opening. An electrolytic capacitor is horizontally disposed within the opening. The electrolytic capacitor includes a first lead electrically coupled to the first solder pad and a second lead electrically coupled to the second solder pad. A solderable pin extends from an enclosure associated with the electrolytic capacitor and is coupled to the third solder pad.

The present application also describes a semiconductor package that includes a printed circuit board defining an opening. An electrolytic capacitor is horizontally disposed within the opening and includes a first lead and a second lead extending from a proximal end of the electrolytic capacitor. An enclosure surrounds at least a distal end of the electrolytic capacitor and defines a support bar. In an example, the first lead, the second lead and the support bar are soldered to respective solder pads provided on a surface of the printed circuit board.

In an other example, the present application describes a semiconductor package that includes a substrate that defines an opening. A first connection means is provided at a proximal side of the opening, a second connection means is provided proximate to the first connection means and a third connection means is provided at a distal side of the opening. An electrolytic capacitor is horizontally disposed within the opening. The electrolytic capacitor includes a first lead and a second lead. A support means extends from an enclosure means associated with the electrolytic capacitor. The first lead, the second lead and the support means are soldered to the first connection means, the second connection means and the third connection means respectively by a reflow soldering process.

This summary is provided to introduce a selection of concepts in a simplified form that are further described below in the Detailed Description. This summary is not intended to identify key features or essential features of the claimed subject matter, nor is it intended to be used to limit the scope of the claimed subject matter.

### BRIEF DESCRIPTION OF THE DRAWINGS

Non-limiting and non-exhaustive examples are described with reference to the following Figures.

FIG. 1A illustrates an example of an existing solution for mounting a capacitor to substrate of a semiconductor package.

FIG. 1B illustrates another example of an existing solution for mounting a capacitor to a substrate of a semiconductor package.

FIG. 2 illustrates a semiconductor package having a horizontally mounted capacitor according to an example.

FIG. 3A illustrates an electrolytic capacitor having an enclosure that enables the electrolytic capacitor to be surface mounted to a substrate according to an example.

FIG. 3B illustrates the electrolytic capacitor of FIG. 3A being surface mounted to a substrate according to an example.

FIG. 4A illustrates an electrolytic capacitor having an enclosure that enables the electrolytic capacitor to be surface mounted to a substrate according to an example.

FIG. 4B illustrates the electrolytic capacitor of FIG. 4A being surface mounted to a substrate according to an example.

FIG. 5A illustrates an electrolytic capacitor having a bracket that enables the electrolytic capacitor to be surface mounted to a substrate according to an example.

FIG. 5B illustrates an electrolytic capacitor having a bracket that enables the electrolytic capacitor to be disposed within an opening defined by a substrate according to an example.

FIG. 6 illustrates an electrolytic capacitor having an enclosure and an associated bracket that enables the electrolytic capacitor to be surface mounted to a substrate according to an example.

FIG. 7 illustrates an electrolytic capacitor having an enclosure and an associated bracket that enables the electrolytic capacitor to be surface mounted to a substrate according to another example.

### DETAILED DESCRIPTION

In the following detailed description, references are made to the accompanying drawings that form a part hereof, and in which are shown by way of illustrations specific embodiments or examples. These aspects may be combined, other aspects may be utilized, and structural changes may be made without departing from the present disclosure. Examples may be practiced as methods, systems or devices. The following detailed description is therefore not to be taken in a limiting sense, and the scope of the present disclosure is defined by the appended claims and their equivalents.

Capacitors, such as electrolytic capacitors (or e-caps), are typically included with various solid-state drives (SSDs) and/or enterprise solid-state drives (eSSDs). Capacitors store and discharge electrical energy and may be used to provide backup power in case of unexpected power outages and/or system failures. For example, a SSD constantly writes and reads data from memory cells. If there is a sudden loss of power, data that is being written or read may be lost or corrupted. However, using a capacitor, an SSD can maintain power long enough to complete any outstanding read and/or write operations.

Capacitors may also help reduce the likelihood of voltage spikes or other disturbances. As a result, a lifespan of the SSD may be prolonged. Give these benefits, it may be beneficial to include high-capacity, high-voltage capacitors in various semiconductor packages.

However, some high-capacity capacitors, such as liquid electrolytic capacitors, may not be easily coupled to a substrate. For example, liquid electrolytic capacitors are typically coupled to a substrate using laser soldering or wave soldering. In other examples, some high-capacity capacitors, such as solid electrolytic capacitors, may have a large footprint and/or size and may not fit in small form factor SSDs.

In order to address the above, the present application describes a semiconductor chip or semiconductor package having a horizontally mounted high-capacity capacitor which enables the semiconductor package to have a reduced height or thickness. Additionally, the high-capacity capacitor may be coupled to a substrate of the semiconductor package using a reflow soldering process.

In an example, the horizontally mounted capacitor is an electrolytic capacitor or other high-capacity capacitor (e.g., a capacitor having a capacity of at least 1000 microfarads (μF) and/or a voltage of at least 35V). The electrolytic capacitor may be a liquid electrolytic capacitor or a solid electrolytic capacitor. The electrolytic capacitor may also include or otherwise be associated with a housing or an enclosure that enables various portions of the electrolytic capacitor and/or its associated enclosure, to be horizontally mounted and coupled to a substrate using a reflow soldering process.

For example and as will be described in greater detail herein, the substrate may define or otherwise include an opening that has a shape and/or dimensions to receive the electrolytic capacitor. The substrate may also include multiple pads (e.g., solder pads) on opposite sides of the opening. Leads of the electrolytic capacitor may be soldered or otherwise coupled to a first set of pads on one side of the opening while a solderable pin or support bar may extend from an enclosure associated with the electrolytic capacitor and may be coupled to a pad on another side of the opening.

As indicated above, in some examples, the electrolytic capacitor is a liquid electrolytic capacitor. In such an example, the enclosure may substantially or entirely surround and/or enclose the electrolytic capacitor and be comprised of a thermal isolation material. As such, the liquid electrolytic capacitor can be soldered to the substrate using a reflow soldering process. In other examples, the electrolytic capacitor is a solid electrolytic capacitor. In such an example, the enclosure may partially surround and/or enclose the electrolytic capacitor. A solderable pin or support bar may extend from the enclosure and be soldered to the substrate using a reflow soldering process. The solderable pin or support bar may be used to maintain a position of the electrolytic capacitor within the opening.

Accordingly, many technical benefits may be realized including, but not limited to, enabling the use of high-capacity and high-voltage capacitors in a small or thin form factor device which may prolong the life of the of the semiconductor chip or SSD, reducing the cost of manufacturing in terms of time and/or money, and reducing the size/footprint of the SSD or semiconductor chip when compared with current solutions.

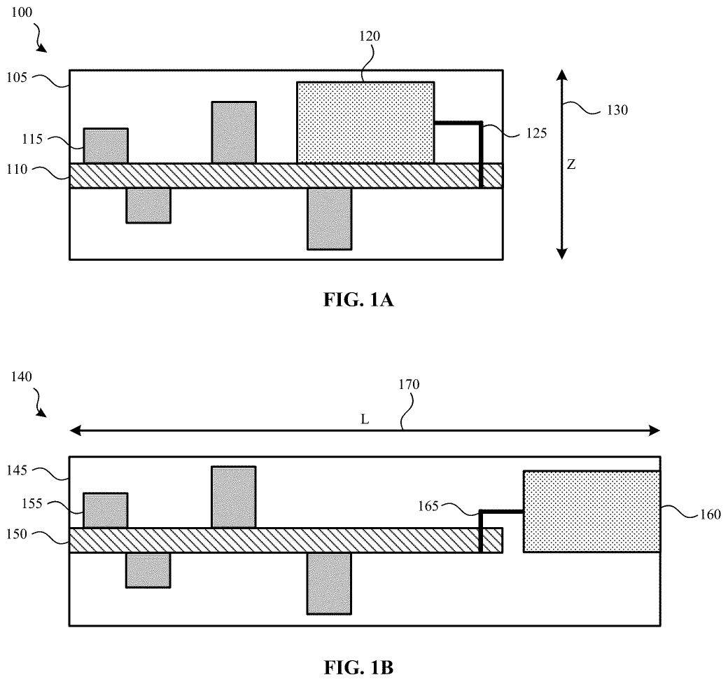

These and other examples will be explained in greater detail below with respect to FIG. 1A-FIG. 7.

FIG. 1A illustrates an example of an existing solution for mounting a capacitor 120 to substrate 110 of a semiconductor package 100. In the example shown, the semiconductor package 100 includes a substrate 110 and various components 115 are mounted on the substrate 110. The capacitor 120 may also be mounted on the substrate 110. As shown, one or more leads 125 of the capacitor 120 are electrically and/or communicatively coupled to the substrate 110.

In an example, the capacitor 120 is a liquid electrolytic capacitor. As such, the capacitor 120 cannot be mounted or coupled to the substrate 110 using a reflow soldering process. Accordingly, the leads 125 of the capacitor 120 are coupled to the substrate 110 using laser soldering or wave soldering. Laser soldering and wave soldering are time consuming and expensive processes, especially when compared to a reflow soldering process.

In another example, the capacitor 120 is a solid electrolytic capacitor. While solid electrolytic capacitors may be surface mounted to the substrate 110 using a reflow soldering process, the size (e.g., a height) of the solid electrolytic capacitor may be prohibitive based on size requirements of the semiconductor package 100. For example, it may be desirable to have a semiconductor package of approximately 6.8 millimeters (mm). However, a height of the solid electrolytic capacitor may be 16 mm or more.

The semiconductor package 100 also includes a lid or housing 105. The housing 105 may enclose or surround the capacitor 120, the substrate 110 and/or the various components 115. As indicated above, an overall height (e.g., a Z dimension) of the semiconductor package 100, represented by the arrow 130, may be based, at least in part, on a size (e.g., a height) of the capacitor 120 and/or a thickness of the housing 105.

In some instances and as indicated above, it may be desirable to reduce an overall height of the semiconductor package 100. One way to reduce the height of the semiconductor package 100 is to use tantalum capacitors. However, tantalum capacitors are expensive and have lower capacity than electrolytic capacitors. In another example and in order to reduce a height of the semiconductor package 100, the electrolytic capacitor may be positioned off to one side of the substrate 110, such as shown in FIG. 1B.

FIG. 1B illustrates another example of an existing solution for mounting a capacitor 160 to a substrate 150 of a semiconductor package 140. Like the example shown in FIG. 1A, the semiconductor package 140 includes a substrate 150, one or more components 155 and a capacitor 160. In this example, and in order to reduce a height (e.g., a Z dimension) of the semiconductor package 140, the capacitor 160 is placed off to the side of the substrate 150. Leads 165 of the capacitor 160 may be electrically and/or communicatively coupled to the substate 150 using laser soldering or wave soldering.

However, while the example shown in FIG. 1B reduces an overall height of the semiconductor package 140 (when compared to the semiconductor package 100 of FIG. 1A), a length, represented by the arrow 170, of the semiconductor package 140 is increased when compared to a length of the semiconductor package 100.

As indicated above, it may be desirable to reduce or otherwise minimize the overall height and length of a semiconductor package while still using high-capacity capacitors.

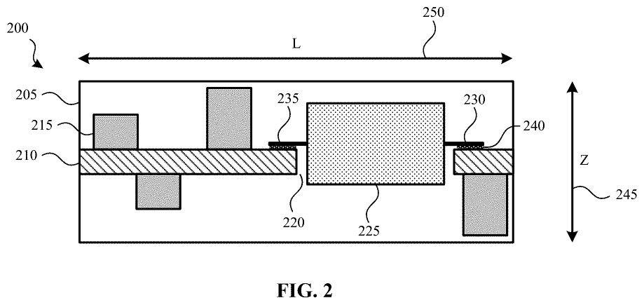

FIG. 2 illustrates a semiconductor package 200 having a horizontally mounted capacitor 225 according to an example. In an example, the semiconductor package 200 may be a SSD or eSSD and the capacitor 225 may be either a solid electrolytic capacitor or a liquid electrolytic capacitor.

The semiconductor package 200 includes a substrate 210. As shown, various components 215 are mounted on one or more surfaces of the substrate 210. In an example, the components 215 are mounted to the various surfaces of the substrate 210 using a reflow soldering process.

In addition, the semiconductor package 200 includes a capacitor 225. The capacitor 225 may be a vertical-type capacitor (e.g., a capacitor that is typically mounted to a substrate in a vertical orientation). However, and as will be explained in greater detail below, the capacitor 225 may be horizontally mounted to the substrate 210 or otherwise disposed in the semiconductor package 200. Additionally, the capacitor 225 is mounted to and communicatively and/or electrically coupled to the surface of the substrate 210 using the same reflow soldering process that was used to mount or otherwise couple the components 215 to the substrate 210. As such, production time and/or cost of the semiconductor package 200 may be reduced when compared with the solutions described with respect to FIG. 1A-FIG. 1B.

In an example, the substrate 210 of the semiconductor package 200 defines an opening 220. The opening 220 may have dimensions that correspond to, or are larger than, the dimensions of the capacitor 225. As such, the capacitor 225 may be horizontally disposed within the opening 220.

The substrate 210 may include one or more pads 240 provided on a first side of the opening 220 and a second side of the opening 220 opposite the first side. In an example, one or more leads 230 of the capacitor 225 are electrically and/or communicatively coupled to the one or more pads 240 on the first side of the opening 220 while a solderable pin or support bar 235 is coupled to a pad 240 on the second side of the opening 220.

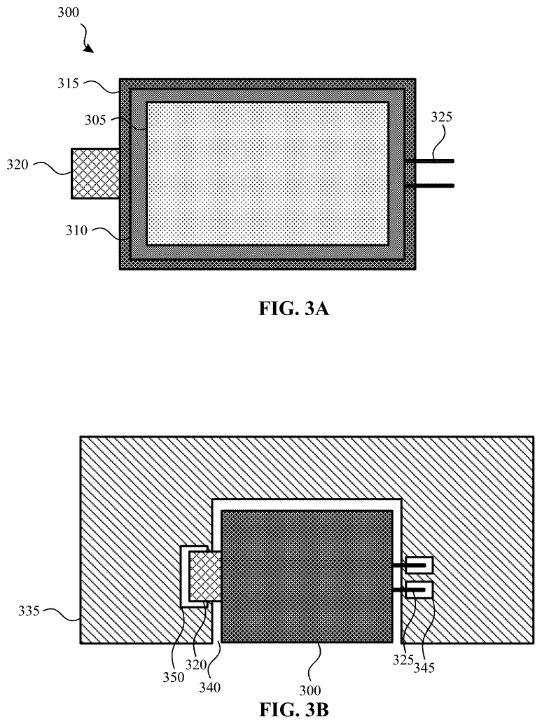

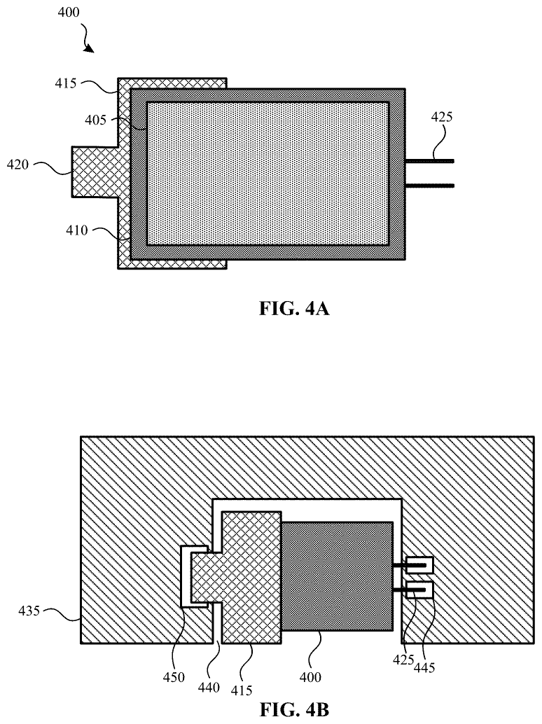

In an example, and as will be explained in greater detail with respect to FIG. 3A-FIG. 4B, the solderable pin or support bar 235 may be part of or otherwise associated with an enclosure that at least partially surrounds the capacitor 225. The solderable pin or support bar may be used to secure the capacitor 225 in the opening 220 while reducing the height (represented by arrow 245) of the semiconductor package 200 when compared to a height of the semiconductor package 100 (FIG. 1A) and reducing the length (represented by arrow 250) of the semiconductor package 200 when compared to a length of the semiconductor package 140 (FIG. 1B).

FIG. 3A illustrates an electrolytic capacitor 300 having an enclosure that enables the electrolytic capacitor 300 to be surface mounted to a substrate according to an example. In an example, the electrolytic capacitor 300 may be similar to the capacitor 225 shown and described with respect to FIG. 2.

In an example, the electrolytic capacitor 300 includes a liquid electrolyte 305. As such, the electrolytic capacitor 300 may be a liquid electrolytic capacitor. The electrolytic capacitor 300 may include a case 310 or housing. In an example, the case 310 or housing is comprised of aluminum, copper, steel or other materials. One or more leads 325 may extend from a middle portion, a center portion or an inner portion of a distal end of the capacitor 300. The leads 325 may be used to electrically and/or communicatively couple the electrolytic capacitor 300 to a substrate.

Typically, and as explained above, liquid electrolytic capacitors cannot undergo a reflow soldering process as heat generated during the reflow soldering process will damage the liquid electrolyte 305. However and as also explained above, laser soldering or wave soldering may be an expensive and/or time consuming process.

In order to address this, the electrolytic capacitor 300 may also include an enclosure 315. In an example, the enclosure 315 substantially surrounds or completely surrounds the electrolytic capacitor 300. In some examples, the enclosure 315 may include or otherwise define apertures or openings that enable the leads 325 to extend beyond the enclosure 315. The enclosure 315 may be comprised of a thermal isolation material such as, for example, silicone, fiberglass, Aerogel or other such materials that can withstand high temperatures that are generated during a reflow soldering process.

The electrolytic capacitor 300 may also include a solderable pin or support bar 320. The support bar 320 may extend from a middle portion, center portion or inner portion of proximal end of the capacitor 300 or enclosure 315 or otherwise extend from an opposite end of the enclosure 315 from which the leads 325 extend. In an example, the support bar 320 may be comprised of the same or similar material that comprises the enclosure 315. In such an example, the support bar 320 may be formed as part of the enclosure 315.

In another example, the support bar 320 may be comprised of a material that is different from the material that forms the enclosure 315. For example, the support bar 320 may be comprised of a copper base having tin plating. Although specific material are mentioned, the support bar 320 may be comprised of any materials. Regardless of the material, the support bar 320 may be used to secure the electrolytic capacitor 300 within an opening of a substrate. For example, the support bar 320 may be a flat or substantially flat and have a square or rectangle shape. As such, a surface of the support bar may be used to secure the electrolytic capacitor 300 to the substrate.

For example, the support bar 320, along with the enclosure 315, may enable the electrolytic capacitor 300, or portions of the electrolytic capacitor 300, to be surface mounted to a substrate and subsequently undergo a reflow soldering process at the same time other components (e.g., components 215 (FIG. 2)) are surface mounted to the substrate.

FIG. 3B illustrates the electrolytic capacitor 300 of FIG. 3A being surface mounted to a substrate 335 according to an example. Like the substrate 210 shown and described with respect to FIG. 2, the substrate 335 defines an opening 340. In an example, a shape and/or one or more dimensions of the opening 340 are substantially equivalent to a shape and/or one or more dimensions of the electrolytic capacitor 300. As such, the electrolytic capacitor 300 may be horizontally disposed or otherwise positioned within the opening 340.

The substrate 335 may also include a first pad 345 (or a first set of pads) at or near a first side of the opening 340. The substrate 335 may also include a second pad 350 (or a second set of pads) at or near a second side of the opening opposite the first side of the opening 340. In an example, the first pad 345 and/or the second pad 350 may be copper pads or solder pads provided on a surface of the substrate 335. Each of the first pad 345 and the second pad 350 may have the same dimensions, similar dimensions or different dimensions. For example, the first pad 345 may have a first set of dimensions based, at least in part, on dimensions of the leads 325 while the second pad 350 may have a second set of dimensions based, at least in part, on the dimensions of the support bar 320.

In an example, when the support bar 320 is positioned on the second pad 350 and the leads 325 are positioned on the first pad 345 (or first and second leads are provided or otherwise positioned on first and second pads respectively), a reflow soldering process may be used to couple the leads 325 to the first pad 345 (or the first set of pads) and couple the support bar 320 to the second pad 350. As explained above, one or more components (e.g., components 215 (FIG. 2)) may also be surface mounted to the substrate during the same reflow soldering process. When the support bar 320 is soldered to the second pad 350, the support bar 320 may help maintain the position of the electrolytic capacitor 300 within the opening 340.

FIG. 4A illustrates an electrolytic capacitor 400 having an enclosure 415 that enables the electrolytic capacitor 400 to be surface mounted to a substrate according to an example. In an example, the electrolytic capacitor 400 may be similar to the capacitor 225 shown and described with respect to FIG. 2.

In this example, the electrolytic capacitor 400 includes a solid electrolyte 405. As such, the electrolytic capacitor 400 may be a solid electrolytic capacitor. The electrolytic capacitor 400 may include a case 410 or housing. In an example, the case 410 or housing is comprised of aluminum, copper, steel or other materials. One or more leads 425 may extend from a middle portion, a center portion or an inner portion of a distal end of the electrolytic capacitor 400. The leads 425 may be used to electrically and/or communicatively couple the electrolytic capacitor 400 to a substrate.

Unlike the liquid electrolytic capacitor 300 (FIG. 3A) that cannot undergo a reflow soldering process, the solid electrolytic capacitor 400 can withstand the heat that is generated during a reflow soldering process. However, the dimensions of the electrolytic capacitor 400 may be prohibitive when trying to reduce an overall thickness or height of a semiconductor package. However, and as will be explained in greater detail below with respect to FIG. 4B, the electrolytic capacitor 400 may include or otherwise be associated with an enclosure 415 that enables the electrolytic capacitor 400 to be mounted on a substrate in a manner that reduces than overall height of the semiconductor package.

For example, the enclosure 415 may be a solderable socket that at least partially surrounds the electrolytic capacitor 400. In some examples, the enclosure 415 may include or otherwise define an aperture that enables a distal end of the electrolytic capacitor 400 to be disposed within the enclosure 415.

In an example, the enclosure 415 may be comprised of copper and/or tin. For example, a base of the enclosure may be comprised of copper and may also include tin plating. Although specific material are mentioned, the enclosure 415 may be comprised of any material. The enclosure 415 may also include a support bar 420 or a solderable pin. The support bar 420 may extend from a middle portion, a center portion or an inner portion of the enclosure 415. In an example, the support bar 420 may be formed as part of the enclosure 415. In another example, the support bar 420 may be coupled to the enclosure 415.

In an example, the support bar 420 is used to secure the electrolytic capacitor 400 within an opening of a substrate. For example, the support bar 420 may be a flat or substantially flat and have a square or rectangle shape. As such, a surface of the support bar 420 may be used to secure the electrolytic capacitor 400 to the substrate.

For example, the support bar 420, may enable the electrolytic capacitor 400, or portions of the electrolytic capacitor 400, to be surface mounted to the substrate and subsequently undergo a reflow soldering process at the same time other components are surface mounted to the substrate.

FIG. 4B illustrates the electrolytic capacitor 400 of FIG. 4A being surface mounted to a substrate 435 according to an example. Like the substrate 210 shown and described with respect to FIG. 2, the substrate 435 defines an opening 440. In an example, a shape and/or one or more dimensions of the opening 440 are substantially equivalent to a shape and/or one or more dimensions of the electrolytic capacitor 400. As such, the electrolytic capacitor 400 may be horizontally disposed or otherwise positioned within the opening 440.

The substrate 435 may also include a first pad 445 (or a first set of pads) at or near a first side of the opening 440. The substrate 435 may also include a second pad 450 (or a second set of pads) at or near a second side of the opening 440 opposite the first side of the opening 440. In an example, the first pad 445 and/or the second pad 450 may be copper pads or solder pads provided on a surface of the substrate 435. Each of the first pad 445 and the second pad 450 may have the same dimensions, similar dimensions or different dimensions. For example, the first pad 445 may have a first set of dimensions based, at least in part, on dimensions of the leads 425 while the second pad 450 may have a second set of dimensions based, at least in part, on the dimensions of the support bar 420 (FIG. 4A).

In an example, when the support bar 420 is positioned on the second pad 450 and the leads 425 are positioned on the first pad 445 (or the first set of pads), a reflow soldering process may be used to electrically couple the leads 425 to the first pad 445 and couple the support bar 420 to the second pad 450. As explained above, one or more components (e.g., components 215 (FIG. 2)) may also be surface mounted to the substrate during the same reflow soldering process. When the support bar 420 is soldered to the second pad 450, the support bar 420 may help maintain the position of the electrolytic capacitor 400 within the opening 440.

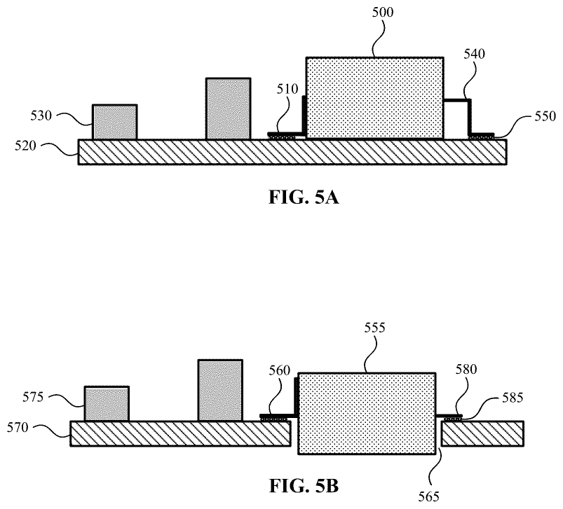

FIG. 5A illustrates an electrolytic capacitor 500 having a bracket 510 that enables the electrolytic capacitor 500 to be surface mounted to a substrate 520 according to an example. In an example, the electrolytic capacitor 500 may be either a solid electrolytic capacitor or a liquid electrolytic capacitor. As such, the electrolytic capacitor 500 may include one or more features disclosed with respect to FIG. 3A-FIG. 4B. Additionally, the electrolytic capacitor 500 may be integrated with a semiconductor package such as, for example, a SSD or eSSD.

In the example shown in FIG. 5A, the electrolytic capacitor 500 is surface mounted to a substrate 520. Various components 530 may also be surface mounted on one or more surfaces of the substrate 520. In an example, the components 530 and the electrolytic capacitor 500 are mounted to the various surfaces of the substrate 530 during the same reflow soldering process.

In an example, the electrolytic capacitor 500 includes a bracket 510. The bracket 510 may extend from a proximal side of the electrolytic capacitor 500. In an example, the bracket is “L” shaped such that a first portion of the bracket 510 is coupled to or extends from the proximal side of the electrolytic capacitor 500 and a second portion is surface mounted to the substrate 520. Although an “L” shape is specifically mentioned, other shapes are contemplated.

In an example, the bracket 510 may be integrated with a case or housing of the electrolytic capacitor 500. In another example, the bracket 510 may be coupled to the proximal side of the electrolytic capacitor 500 prior to or when the electrolytic capacitor 500 is surface mounted to the substrate 520. In another example, the bracket 510 may be used in place of the solderable pin or support bar described herein with respect to FIG. 2-FIG. 4B.

One or more leads 540 may extend from a distal side of the electrolytic capacitor 500. In an example, the one or more leads 540 are arranged in a “Z” shape. For example, a first portion of the one or more leads 540 may extend parallel or substantially parallel from the distal side of the electrolytic capacitor 500, a second portion of the one or more leads 540 may extend vertically or substantially vertically from the first portion, and a third portion of the one or more leads 540 may extend horizontally or substantially horizontally from the second portion. Although a “Z” shape is specifically mentioned, other shapes or arrangements are contemplated.

The substrate 520 may include one or more pads 550 provided on a first side of the electrolytic capacitor 500 and a second side of the electrolytic capacitor 500 opposite the first side. In an example, the one or more leads 540 of the electrolytic capacitor 500 are electrically and/or communicatively coupled to the one or more pads 550 on the first side while the bracket 510 is coupled to a pad 550 on the second side.

FIG. 5B illustrates an electrolytic capacitor 555 having a bracket 560 that enables the electrolytic capacitor 555 to be disposed within an opening 565 defined by a substrate 570 according to an example. In an example, the electrolytic capacitor 555 may be either a solid electrolytic capacitor or a liquid electrolytic capacitor. As such, the electrolytic capacitor 555 may include one or more features disclosed with respect to FIG. 3A-FIG. 4B. Additionally, the electrolytic capacitor 500 may be integrated with a semiconductor package such as, for example, a SSD or eSSD.

In the example shown in FIG. 5B, the electrolytic capacitor 555 is surface mounted to the substrate 570. Various components 575 may also be surface mounted on one or more surfaces of the substrate 570. In an example, the components 575 and the electrolytic capacitor 555 are mounted to the various surfaces of the substrate 570 during the same reflow soldering process.

As with other examples described herein, the electrolytic capacitor 555 includes a bracket 560. The bracket 560 may extend from a proximal side of the electrolytic capacitor 555. In an example, the bracket is “L” shaped such as previously described. Although an “L” shape is specifically mentioned, other shapes are contemplated.

In an example, the bracket 560 may be integrated with a case or housing of the electrolytic capacitor 555. In another example, the bracket 560 may be coupled to the proximal side of the electrolytic capacitor 555 prior to or when the electrolytic capacitor 555 is surface mounted to the substrate 570. In another example, the bracket 560 may be used in place of the solderable pin or support bar described herein with respect to FIG. 2-FIG. 4B.

One or more leads 580 may extend from a distal side of the electrolytic capacitor 555. However, because the electrolytic capacitor 555 is disposed within the opening 565 defined by the substrate 570, the leads 580 may extent horizontally or substantially horizontally from the distal side of the electrolytic capacitor 555.

The substrate 570 may also include one or more pads 585 provided on a first side of the opening 565 and on a second side of the opening 565. In an example, the one or more leads 540 of the electrolytic capacitor 500 are electrically and/or communicatively coupled to the one or more pads 585 on the first side of the opening 565 while the bracket 560 is coupled to a pad 585 on the second side of the opening 565.

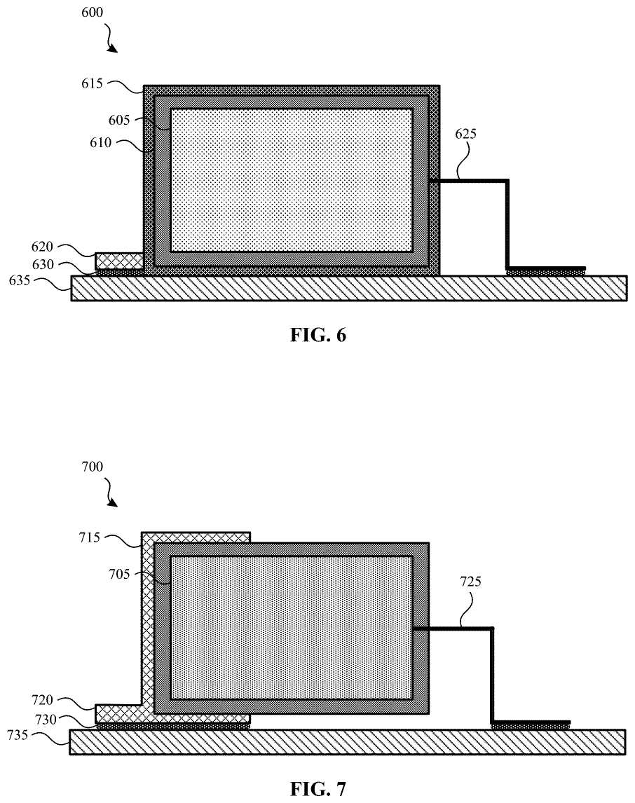

FIG. 6 illustrates an electrolytic capacitor 600 having an enclosure 615 and an associated bracket 620 that enables the electrolytic capacitor 600 to be surface mounted to a substrate 635 according to an example. The electrolytic capacitor 600 may be similar to the electrolytic capacitor 300 shown and described with respect to FIG. 3A.

For example, the electrolytic capacitor 600 includes a liquid electrolyte 605. As such, the electrolytic capacitor 600 may be a liquid electrolytic capacitor. The electrolytic capacitor 600 may also include a case 610 or housing. One or more leads 625 may extend from a middle portion, a center portion or an inner portion of a distal end of the capacitor 600. The one or more leads 625 may be configured in a “Z” shape such as previously described. The one or more leads 625 may be used to electrically and/or communicatively couple the electrolytic capacitor 600 to the substrate 635. For example, the one or more leads 625 may be electrically coupled to one or more pads 630.

The electrolytic capacitor 600 may also include an enclosure 615. In an example, the enclosure 615 substantially surrounds or completely surrounds the electrolytic capacitor 600. The enclosure 615 may be comprised of a thermal isolation material that can withstand high temperatures that are generated during a reflow soldering process such as previously described.

The electrolytic capacitor 600 may also include a bracket 620. The bracket 620 may be similar to the bracket 510 shown and described with respect to FIG. 5A. For example, the bracket 620 may extend from a proximal end of the capacitor 600 or the enclosure 615 and be coupled to the substrate 635 via a pad 630. In an example, the bracket 620 may be comprised of the same or similar material that comprises the enclosure 615. In such an example, the bracket 620 may be formed as part of the enclosure 615.

In another example, the bracket 620 may be comprised of a material that is different from the material that forms the enclosure 615. For example, the bracket 620 may be comprised of a copper base having tin plating. Although specific material are mentioned, the bracket 620 may be comprised of any materials. Regardless of the material, the support bar bracket 620 may be used to secure the electrolytic capacitor 600 to the substrate 635.

For example, the bracket 620, along with the enclosure 615, may enable the electrolytic capacitor 600, or portions of the electrolytic capacitor 600, to be surface mounted to the substrate 635 and subsequently undergo a reflow soldering process such as previously described.

FIG. 7 illustrates an electrolytic capacitor 700 having an enclosure 715 and an associated bracket 720 that enables the electrolytic capacitor 700 to be surface mounted to a substrate 735 according to an example. The electrolytic capacitor 700 may be similar to the electrolytic capacitor 400 shown and described with respect to FIG. 4A.

In an example, the electrolytic capacitor 700 includes a solid electrolyte 705. As such, the electrolytic capacitor 700 is a solid electrolytic capacitor. The electrolytic capacitor 700 may include a case 710 or housing such as previously described with respect to FIG. 4A. The electrolytic capacitor 700 also includes one or more leads 725 arranged in a “Z” configuration such as previously described. The leads 725 may be used to electrically and/or communicatively couple the electrolytic capacitor 700 to one or more pads 730 provided on surface of the substrate 735.

As briefly explained, the electrolytic capacitor 700 may also include an enclosure 715. The enclosure 715 may be a solderable socket that at least partially surrounds the electrolytic capacitor 700. In some examples, the enclosure 715 may include or otherwise define an aperture that enables a distal end of the electrolytic capacitor 700 to be disposed within the enclosure 715.

In an example, the enclosure 715 may be comprised of copper and/or tin. For example, a base of the enclosure may be comprised of copper and may also include tin plating. Although specific material are mentioned, the enclosure 715 may be comprised of any material. The enclosure 715 may also include a bracket 720 that extends from the enclosure 715. In an example, the bracket 720 may be formed as part of the enclosure 715. In another example, the bracket 720 may be coupled to the enclosure 715.

In an example, the bracket 720 is used to secure the electrolytic capacitor 700 to the substrate 735 during a reflow soldering process. For example, the bracket 720 may enable the electrolytic capacitor 700, or portions of the electrolytic capacitor 700, to be surface mounted to the substrate 735 (e.g., via one or more pads 730) and subsequently undergo a reflow soldering process at the same time other components are surface mounted to the substrate 735.

In accordance with the above, examples of the present disclosure describe a semiconductor package, comprising: a substrate defining an opening; a first solder pad provided on a surface of the substrate at a proximal side of the opening; a second solder pad provided on the surface of the substrate proximate to the first solder pad; a third solder pad provided on the surface of the substrate at a distal side of the opening; an electrolytic capacitor horizontally disposed within the opening and comprising a first lead electrically coupled to the first solder pad and a second lead electrically coupled to the second solder pad; and a solderable pin extending from an enclosure associated with the electrolytic capacitor and coupled to the third solder pad. In an example, the electrolytic capacitor is a liquid electrolytic capacitor. In an example, the enclosure comprises a thermal isolation material that substantially surrounds the electrolytic capacitor. In an example, the electrolytic capacitor is a solid electrolytic capacitor. In an example, the enclosure at least partially surrounds a distal end of the electrolytic capacitor. In an example, the solderable pin is comprised of one or more of copper and tin. In an example, the first lead is electrically coupled to the first solder pad, the second lead is electrically coupled to the second solder pad, and the solderable pin is electrically coupled to the third solder pad by reflow soldering. In an example, the solderable pin provides support for the electrolytic capacitor.

In another example, a semiconductor package is described. The semiconductor package includes a printed circuit board defining an opening; an electrolytic capacitor horizontally disposed within the opening and comprising a first lead and a second lead extending from a proximal end of the electrolytic capacitor; and an enclosure surrounding at least a distal end of the electrolytic capacitor and defining a support bar, wherein the first lead, the second lead and the support bar are soldered to respective solder pads provided on a surface of the printed circuit board. In an example, the electrolytic capacitor is a liquid electrolytic capacitor. In an example, the enclosure comprises a thermal isolation material. In an example, the electrolytic capacitor is a solid electrolytic capacitor. In an example, the support bar is comprised of one or more of copper and tin. In an example, the support bar provides support for the distal end of the electrolytic capacitor.

Examples also describe a semiconductor package, comprising: a substrate defining an opening; a first connection means provided at a proximal side of the opening; a second connection means provided proximate to the first connection means; a third connection means provided at a distal side of the opening; an electrolytic capacitor horizontally disposed within the opening and comprising a first lead and a second lead; and a support means extending from an enclosure means associated with the electrolytic capacitor, wherein the first lead, the second lead and the support means are soldered to the first connection means, the second connection means and the third connection means respectively by a reflow soldering process. In an example, the electrolytic capacitor has a capacitance of at least one-thousand microfarads (μF). In an example, a height of the semiconductor package is less than approximately 6.8 mm. In an example, the electrolytic capacitor is a liquid electrolytic capacitor. In an example, the enclosure means comprises a thermal isolation material. In an example, the electrolytic capacitor is a solid electrolytic capacitor.

The description and illustration of one or more aspects provided in the present disclosure are not intended to limit or restrict the scope of the disclosure in any way. The aspects, examples, and details provided in this disclosure are considered sufficient to convey possession and enable others to make and use the best mode of claimed disclosure.

The claimed disclosure should not be construed as being limited to any aspect, example, or detail provided in this disclosure. Regardless of whether shown and described in combination or separately, the various features (both structural and methodological) are intended to be selectively rearranged, included or omitted to produce an embodiment with a particular set of features. Having been provided with the description and illustration of the present application, one skilled in the art may envision variations, modifications, and alternate aspects falling within the spirit of the broader aspects of the general inventive concept embodied in this application that do not depart from the broader scope of the claimed disclosure.

References to an element herein using a designation such as “first,” “second,” and so forth does not generally limit the quantity or order of those elements. Rather, these designations may be used as a method of distinguishing between two or more elements or instances of an element. Thus, reference to first and second elements does not mean that only two elements may be used or that the first element precedes the second element. Additionally, unless otherwise stated, a set of elements may include one or more elements.

Terminology in the form of “at least one of A, B, or C” or “A, B, C, or any combination thereof” used in the description or the claims means “A or B or C or any combination of these elements.” For example, this terminology may include A, or B, or C, or A and B, or A and C, or A and B and C, or 2A, or 2B, or 2C, or 2A and B, and so on. As an additional example, “at least one of: A, B, or C” is intended to cover A, B, C, A-B, A-C, B-C, and A-B-C, as well as multiples of the same members. Likewise, “at least one of: A, B, and C” is intended to cover A, B, C, A-B, A-C, B-C, and A-B-C, as well as multiples of the same members.

Similarly, as used herein, a phrase referring to a list of items linked with “and/or” refers to any combination of the items. As an example, “A and/or B” is intended to cover A alone, B alone, or A and B together. As another example, “A, B and/or C” is intended to cover A alone, B alone, C alone, A and B together, A and C together, B and C together, or A, B, and C together.

What is claimed is:

1. A semiconductor package, comprising:
a substrate defining an opening;
a first solder pad provided on a surface of the substrate at a proximal side of the opening;
a second solder pad provided on the surface of the substrate proximate to the first solder pad;
a third solder pad provided on the surface of the substrate at a distal side of the opening;
an electrolytic capacitor horizontally disposed within the opening and comprising a first lead electrically coupled to the first solder pad and a second lead electrically coupled to the second solder pad; and
a solderable pin extending from an enclosure associated with the electrolytic capacitor and coupled to the third solder pad.

2. The semiconductor package of claim 1, wherein the electrolytic capacitor is a liquid electrolytic capacitor.

3. The semiconductor package of claim 2, wherein the enclosure comprises a thermal isolation material that substantially surrounds the electrolytic capacitor.

4. The semiconductor package of claim 1, wherein the electrolytic capacitor is a solid electrolytic capacitor.

5. The semiconductor package of claim 4, wherein the enclosure at least partially surrounds a distal end of the electrolytic capacitor.

6. The semiconductor package of claim 1, wherein the solderable pin is comprised of one or more of copper and tin.

7. The semiconductor package of claim 1, wherein the first lead is electrically coupled to the first solder pad, the second lead is electrically coupled to the second solder pad, and the solderable pin is electrically coupled to the third solder pad by reflow soldering.

8. The semiconductor package of claim 1, wherein the solderable pin provides support for the electrolytic capacitor.

9. A semiconductor package, comprising:
a printed circuit board defining an opening;
an electrolytic capacitor horizontally disposed within the opening and comprising a first lead and a second lead extending from a proximal end of the electrolytic capacitor; and
an enclosure surrounding at least a distal end of the electrolytic capacitor and defining a support bar, wherein the first lead, the second lead and the support bar are soldered to respective solder pads provided on a surface of the printed circuit board.

10. The semiconductor package of claim 9, wherein the electrolytic capacitor is a liquid electrolytic capacitor.

11. The semiconductor package of claim 10, wherein the enclosure comprises a thermal isolation material.

12. The semiconductor package of claim 9, wherein the electrolytic capacitor is a solid electrolytic capacitor.

13. The semiconductor package of claim 9, wherein the support bar is comprised of one or more of copper and tin.

14. The semiconductor package of claim 9, wherein the support bar provides support for the distal end of the electrolytic capacitor.

15. A semiconductor package, comprising:
a substrate defining an opening;
a first connection means provided at a proximal side of the opening;
a second connection means provided proximate to the first connection means;
a third connection means provided at a distal side of the opening;
an electrolytic capacitor horizontally disposed within the opening and comprising a first lead and a second lead; and
a support means extending from an enclosure means associated with the electrolytic capacitor, wherein the first lead, the second lead and the support means are soldered to the first connection means, the second connection means and the third connection means respectively by a reflow soldering process.

16. The semiconductor package of claim 15, wherein the electrolytic capacitor has a capacitance of at least one-thousand microfarads (μF).

17. The semiconductor package of claim 15, wherein a height of the semiconductor package is less than approximately 6.8 mm.

18. The semiconductor package of claim 15, wherein the electrolytic capacitor is a liquid electrolytic capacitor.

19. The semiconductor package of claim 18, wherein the enclosure means comprises a thermal isolation material.

20. The semiconductor package of claim 15, wherein the electrolytic capacitor is a solid electrolytic capacitor.
